(19) United States
(12) Patent Application Publication
(10) Pub. No.: US 2009/0250258 A1
(43) Pub. Date: Oct. 8, 2009

(54) Wiring Substrate, Semiconductor Package, Electronic Instrument, And Wiring Substrate Manufacturing Method

(75) Inventors: Ryo Warigaya, Tokyo (JP); Kenji Hisamatsu, Tokyo (JP); Isao Kato, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 12/486,676

(22) Filed: Jun. 17, 2009

Related U.S. Application Data
(63) Continuation of application No. PCT/JP2008/058962, filed on May 15, 2008.

(30) Foreign Application Priority Data
May 18, 2007 (JP) 2007-133414
Feb. 29, 2008 (JP) 2008-049811

(51) Int. Cl. H05K 1/18; H05K 1/11

(52) U.S. Cl. 174/260; 174/261

(57) ABSTRACT

One embodiment of the invention is a wiring substrate including an insulating base material layer, a metal layer on the insulating base material layer, and a solder resist laminated to the most superficial surface of the wiring substrate above the insulating base material layer, wherein the metal layer has a loop shaped pattern formed along the edge of the insulating base material layer, and the solder resist is formed in such a way that one portion of the pattern is exposed from, and one portion covered with, an extremity of the solder resist on the edge side, along the pattern.

### CROSS-REFERENCE TO RELATED APPLICATIONS

This is a Continuation Application of PCT Application No. PCT/JP2008/058962, filed May 15, 2008. PCT Application No. PCT/JP2008/058962 is based on and claims the benefit of priority from the Japanese Patent Application number 2007-133414, filed on May 18, 2007 and the Japanese Patent Application number 2008-049811, filed on Feb. 29, 2008. The entire contents of Application numbers PCT/JP2008/058962, 2007-133414, and 2008-049811 are incorporated herein by reference.

(Claims in this application were allowed on Apr. 14, 2009 by Japan Patent Office)

### BACKGROUND OF THE INVENTION

1. Field of the Invention

The present invention relates to a wiring substrate, and particularly, to a wiring substrate whose surface is covered with a solder resist, and a wiring substrate to which a solder resist is laminated at a manufacturing stage.

2. Description of Related Art

When connecting electrodes on a wiring substrate to the wiring substrate, lead wires, and the like, with solder, a lamination of a solder resist to a surface of the wiring substrate is carried out, for the purpose of preventing solder from flowing out to an adjacent electrode.

In recent years, in a method of manufacturing the wiring substrate, in order to arrange in such a way as to make the quality thereof as consistent as possible, as well as manufacturing a large number of wiring substrates, a method has been employed in which a manufacturing method is used which forms a large number of wiring substrates on one substrate, which are ultimately cut into separate pieces, and shipped as products.

When cutting wiring substrates manufactured by a multifacing (a method of obtaining a plurality of wiring substrates by cutting simultaneously manufactured parent substrates) into separate pieces, in the event that a metal such as copper exists on cut surfaces, a cutting blade becomes quick to wear away.

Therein, in order to prevent the wear of the blade, an arrangement is adopted such that copper of wiring or the like is removed from a cut portion by an etching, placing as small a burden as possible on the cut portion, and the wiring substrates are cut into separate pieces with that portion as a cut pattern.

However, when cutting the wiring substrates on which the cut pattern is formed, the wiring substrates are deformed due to being thin, whereby a solder resist laminated to the wiring substrates separates from an insulating resin, and also, by cutting the solder resist, the solder resist suffers cracks in the cut portion.

It has been found that, by removing a copper foil and cutting the wiring substrates, the adhesion between the solder resist and the insulating resin is lower than the adhesion between the copper and the solder resist, and this is the reason why a separation starts with the portion of the solder resist and insulating resin.

Also, in particular, with a substrate which has no core substrate in a multilayer wiring substrate, a thin substrate, the total thickness of a wiring substrate laminated to which is 500 μm or less, or a flexible substrate, as a warpage is likely to occur in such a substrate, and a stress is likely to concentrate in one portion, there has been a problem in that this kind of solder resist separation phenomenon is likely to occur.

JP-A-10-22590 and JP-A-11-231522 are examples of related art.

### SUMMARY OF THE INVENTION

An object of the invention is to provide a wiring substrate in which a solder resist will not separate easily.

One embodiment of the invention is a wiring substrate including an insulating base material layer, a metal layer on the insulating base material layer, and a solder resist laminated to the most superficial surface of the wiring substrate above the insulating base material layer, wherein the metal layer has a loop shaped pattern formed along the edge of the insulating base material layer, and the solder resist is formed in such a way that one portion of the pattern is exposed from, and one portion covered with, an extremity of the solder resist on the edge side, along the pattern.

### BRIEF DESCRIPTION OF THE DRAWINGS

FIG. 1 is a sectional view illustrating a configuration of a wiring substrate according to an embodiment of the invention;

FIGS. 2A and 2B are sectional views showing the wiring substrate according to the embodiment of the invention;

FIG. 3 is a plan view showing the wiring substrate according to the embodiment of the invention;

FIG. 4 is a plan view showing the wiring substrate according to the embodiment of the invention;

FIG. 5 is a plan view showing the wiring substrate according to the embodiment of the invention;

FIG. 6 is a plan view showing the wiring substrate according to the embodiment of the invention;

FIG. 7 is a plan view showing cutting positions of the wiring substrates according to the embodiment of the invention; and

FIG. 8 is a schematic diagram illustrating a roll-to-roll method.

### DETAILED DESCRIPTION OF THE INVENTION

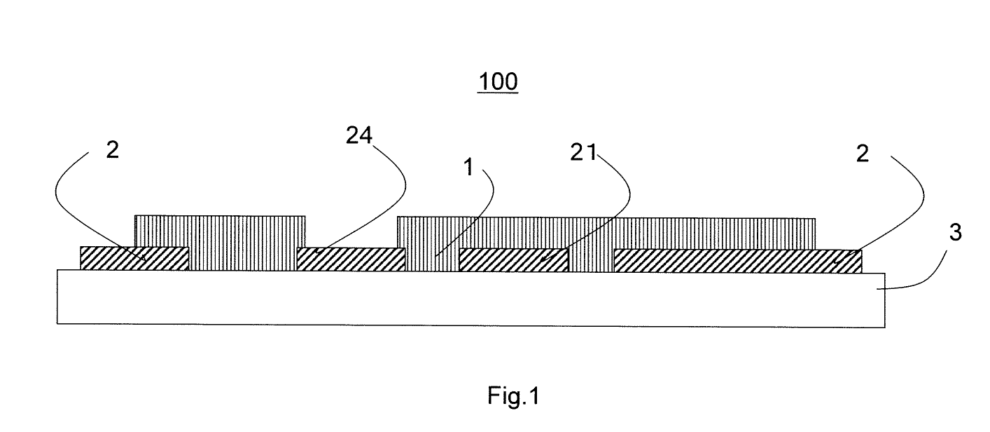

As shown in FIG. 1, a wiring substrate 100 according to an embodiment of the invention has a metal layer 2 on the main surface thereof on an insulating base material layer 3, and has a solder resist 1 on the metal layer 2 lying at the edge of the main surface on the insulating base material layer 3. In FIG. 1, a via hole, wiring on the opposite surface, and the like are omitted. The metal layer 2 includes a wiring pattern 21 and an electrode 24.

With the wiring substrate 100 according to the embodiment of the invention, it is preferable that the solder resist 1 is laminated to the insulating base material layer 3 having the metal layer 2, which has a copper foil, exposed from the main surface. The wiring substrate 100 is configured laminating one or more insulating base material layers 3 and one or more metal layers 2. The wiring substrate 100 is one wherein, one insulating base material layer 3 and one metal layer 2 being formed, as shown in FIG. 1, they are laminated one onto the other, and the solder resist 1 is laminated to the most superficial surface (the top in FIG. 1).

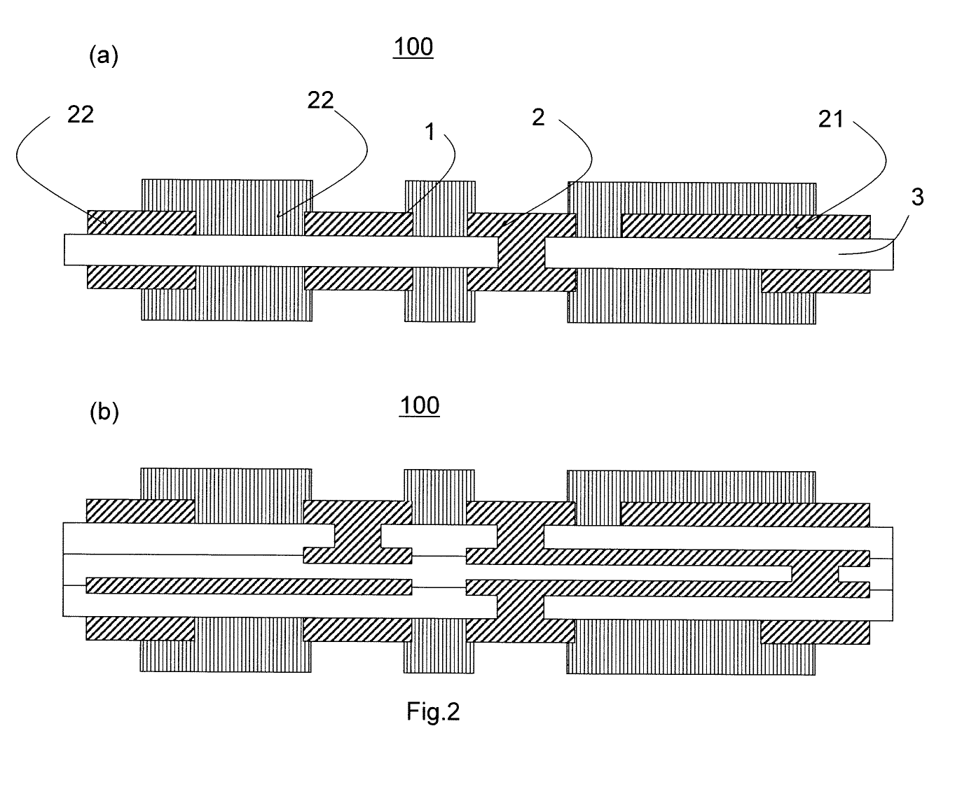

As shown in FIGS. 2A and 2B, the wiring substrate 100 according to the embodiment of the invention is one wherein the metal layer 2 and the solder resist 1 are formed on each surface of the insulating base material layer 3, representing one with a multilayer configuration. The wiring pattern 21 and a dummy wiring pattern are one portion of the metal layer 2. In FIGS. 2A and 2B, the metal layer 2 is formed on either surface of the insulating base material layer 3, along the pattern extremity of the solder resist 1 but, as it is also possible to form it on only one surface of the insulating base material layer 3, the invention is not necessarily limited to this. By forming a plurality of insulating base material layers 3 and a plurality of metal layers 2, it is possible to apply the invention to a buildup wiring substrate configured laminating these insulating base material layers 3 and metal layers 2 in an alternate manner.

As the metal layer 2 according to the embodiment of the invention, it is possible to use a layer formed of a copper foil, a layer formed of a copper plating layer and a metal paste, or the like, but the invention is not necessarily limited to these. Apart from copper, it is possible to use a metal material, such as aluminum or silver, which can be used in wiring. In the event that a metal foil or a metal plating layer is used as the metal layer 2, it is possible to, after forming the copper foil or copper plating layer on the insulating base material layer 3, etch it, forming the metal layer 2. Also, in the event that a metal paste is used as the metal layer 2, it is possible to print the metal paste in a desired pattern. As will be described hereafter, a metal layer 2, one portion of which is exposed from the solder resist 1 at the extremity of the solder resist 1 edge, can be included in the metal layer 2. The wiring pattern 21 and dummy wiring pattern of the metal layer 2, including a ground layer, are simultaneously formed, thereby forming the metal layer 2.

The wiring substrate 100 according to the embodiment of the invention has a feature of including the metal layer 2 in the edge pattern of the main surface. That is, one portion of the extremity of the solder resist 1 is on the metal layer 2. It is acceptable to provide the metal layer 2 as one portion of the wiring pattern 21 or one portion of ground wiring (not shown), and it is also acceptable to make the metal layer 2 the dummy wiring pattern in order to provide the metal layer 2 at the extremity of the solder resist 1. As the adhesion of the solder resist 1 to the metal layer 2 is higher than the adhesion of the insulating base material layer 3, by providing the metal layer 2 beneath the extremity of the solder resist 1, it is possible to prevent a separation of the solder resist 1. For this reason, it is desirable to utilize a copper foil or a copper plating layer as the metal layer 2.

The solder resist 1 according to the embodiment of the invention not particularly being limited as long as it is a resin with electrical isolation, it is possible to select from among common resist materials of an epoxy system, phenolic resin system, xylene system, acrylic system, polyimide system, and the like. In the event of a photosensitive resin, after laminating a resist onto the metal layer 2, it is possible, by exposing and developing it, to selectively expose the wiring pattern 21 or dummy wiring pattern, which is the metal layer 2. It is also acceptable to use a thermosetting resin as another example. A pattern formation is possible with each kind of printing method such as a screen printing. By laminating a metal foil, a metal plating layer, or the like, which is the metal layer 2 on the insulating base material layer 3, it is possible to prevent the extremity of the solder resist 1 from being on the insulating base material layer 3, formed of polyimide or the like which is more likely to separate. By this means, it is possible to prevent the solder resist 1 from coming off the insulating base material layer 3.

As the insulating base material layer 3 according to the embodiment of the invention, apart from an organic insulating base material, such as a polyimide resin or a glass/epoxy resin, it is possible to use a ceramic insulating base material, such as an aluminum-oxide sintered body or an aluminum-nitride sintered body, but the invention is not necessarily limited to these.

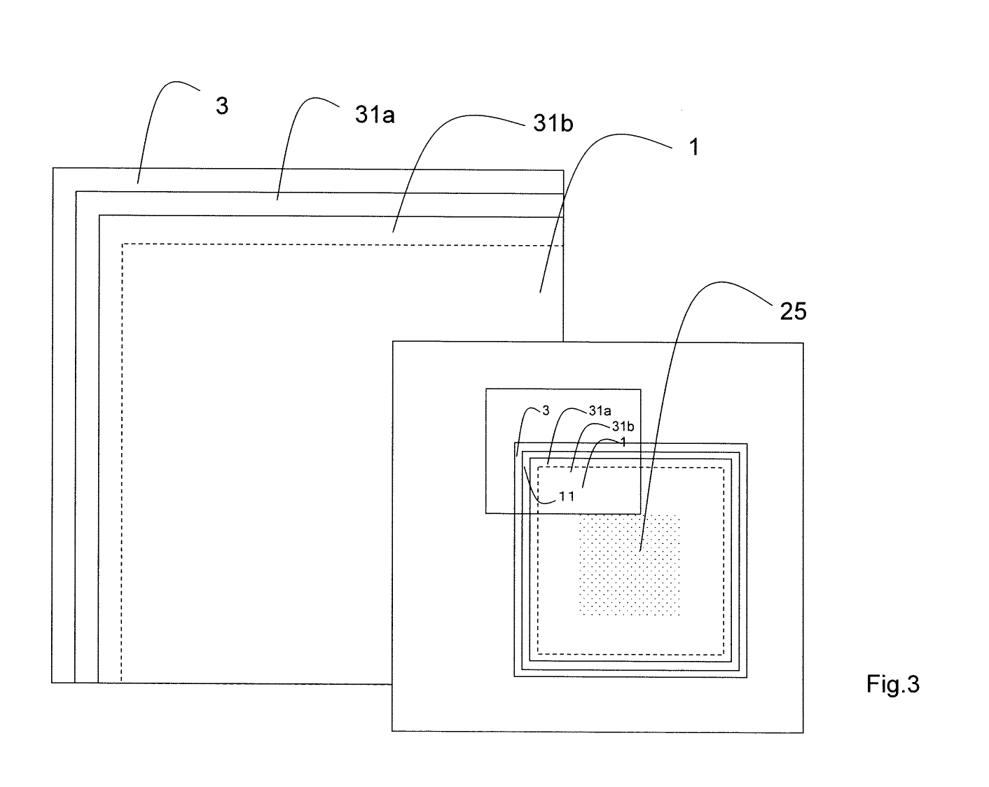

As shown in FIG. 3, the insulating base material layer 3 includes a metal layer (an exposed portion) 31a, which has an extremity disposed a first distance inward from the extremity of the insulating base material layer 3, and the solder resist 1 which, being formed on the metal layer (exposed portion) 31a, has an extremity disposed a second distance inward from the extremity of the metal layer (exposed portion) 31a. The first distance refers to a width of the metal layer (exposed layer) 31a exposed from the solder resist 1. Also, the second distance refers to a width of the portion in which a metal layer (beneath the solder resist 1) 31b and the solder resist 1 overlap each other.

In the embodiment of the invention, it is preferable that a metal layer, particularly, a dummy wiring pattern, is formed in a band shape extending along the extremity of the solder resist 1. That is, the extremity of the resist of the solder resist is positioned on the band shaped metal layer. A simplest configuration of the embodiment of the invention being such that the band shaped metal layer is of a loop shape closed along the extremity, as the metal layer exists at an extremity of the solder resist 1 at any edge, it is possible to completely prevent a separation of the solder resist 1 from the extremity of the pattern. However, it is also acceptable that the metal layer is discontinued in one portion, as will be described hereafter.

In this way, as a separation of the solder resist 1 occurs from the extremity thereof, it is possible to efficiently prevent the separation by the metal layer being formed in a band shape extending along the extremity of the solder resist 1, and also, the separation prevention is also efficient as it is possible to widen a wiring region inside the wiring substrate 100.

As the band shaped metal layer is exposed a certain line width (the first distance) from the solder resist 1, and overlaps a certain line width (the second distance) underneath the solder resist 1, it is possible to obtain a stable separation prevention effect. That is, in other words, as it is possible, by the metal layer being disposed straddling a certain region between the outer and inner edges of the solder resist 1 boundary, to accomplish the purpose even in the event that a displacement of the solder resist 1 from an ideal position of the pattern boundary is occurring, there is a working effect in that no problem arises in quality. From this point of view, it is preferable that the metal layer configures an edge pattern formed along the edge of the insulating base material layer 3, and that the width of the edge pattern is 20 μm or more. In the event that the width of the edge pattern is less than 20 μm, it is not possible to sufficiently take up a manufacturing margin, particularly, an overlapping region (which needs 10 μm or more), and there is a danger that the separation prevention effect of the solder resist 1 decreases. Also, in the event that the width of the edge pattern increases, the separation prevention effect of the solder resist 1 is saturated, but it is possible to take up a wide manufacturing margin.

As shown in FIG. 3, the metal layer is disposed at the edge of the wiring substrate 100. Then, by forming the extremity of the solder resist 1 on the metal layer, it is possible to prevent the solder resist 1 from separating. With the metal layer, by increasing an anchor effect using a surface treatment, such as a roughening process, before laminating the solder resist 1, the separation prevention effect of the solder resist 1 is further improved. As the roughening process, it is possible to use a roughening method, such as a chemical polishing using a roughening agent, or a physical polishing.

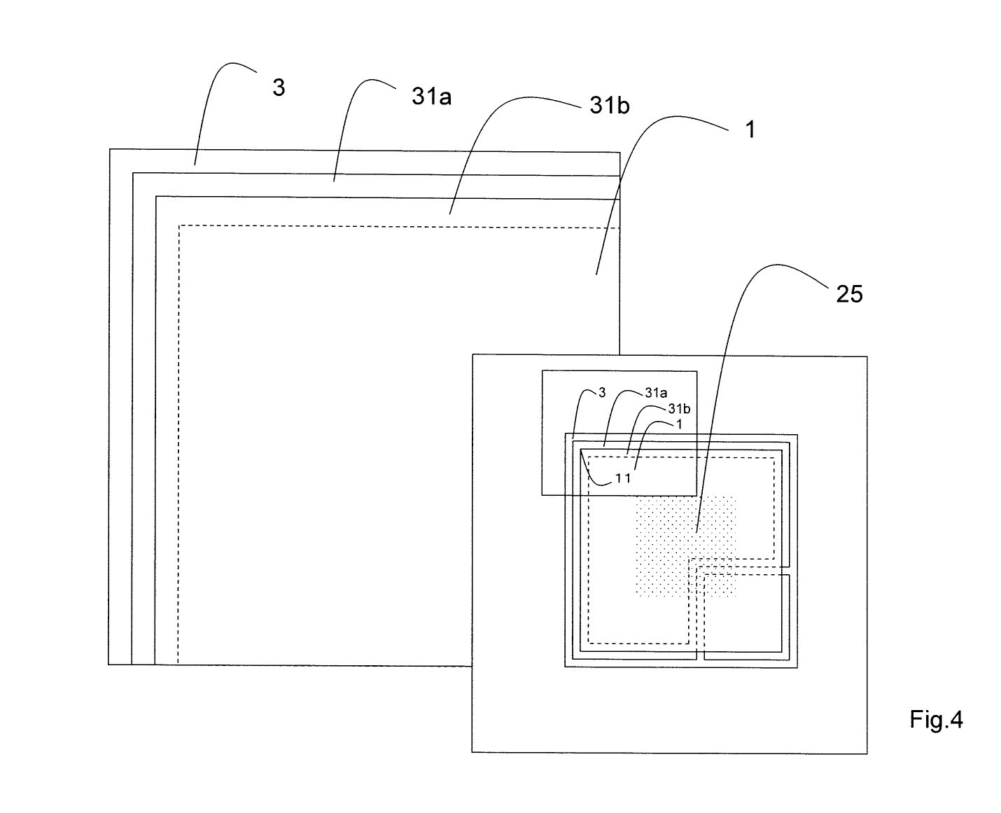

As shown in FIG. 4, in the event that the inward metal layer is affected, it is possible to use one portion of the metal layer, or one portion of the ground wiring (combined as the metal layer), as the edge pattern. The metal layer according to the embodiment of the invention includes the wiring pattern including the ground wiring, and the other so-called dummy wiring pattern.

As shown in FIG. 4, in the event that no continuous edge pattern can be formed because the inward metal layer has a problem, and the extremity of the solder resist 1 exists on the insulating base material layer 3, by making a space between the metal layer and metal layer on either side of the extremity of the solder resist 1 one millimeter or less, it is possible to maintain the separation prevention effect of the solder resist 1. This is because the extremity of the solder resist 1 is protected by the adjacent metal layers even in the event that no metal layer exists at the extremity of the solder resist 1. However, in the event that the total area of the space occupies a half or more of the edge pattern which is supposed to exist, as a portion which is likely to separate increases in comparison with a separation prevention portion, and it is not possible to sufficiently obtain the separation prevention effect, it is desirable that 50% or more of the extremity of the solder resist 1 is on the metal layer.

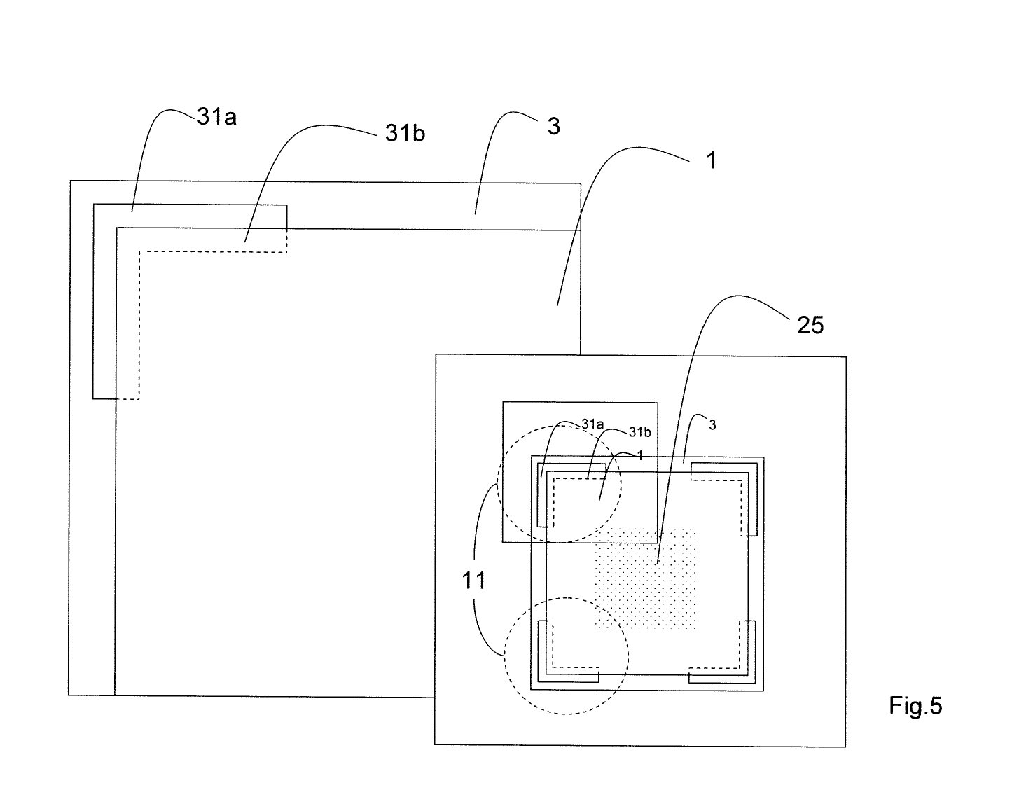

From another point of view, the kinds of portion shown in corners 11 of the solder resist 1 of FIG. 5, being portions from which the solder resist 1 are likely to separate due to a shock such as a bending of the insulating base material layer 3, have the effect of preventing the separation by being protected. For this reason, by disposing metal layers at least only in the portions of the corners 11 of the solder resist, as shown in FIG. 5, it is possible to obtain the separation prevention effect of the solder resist 1 at the corners 11.

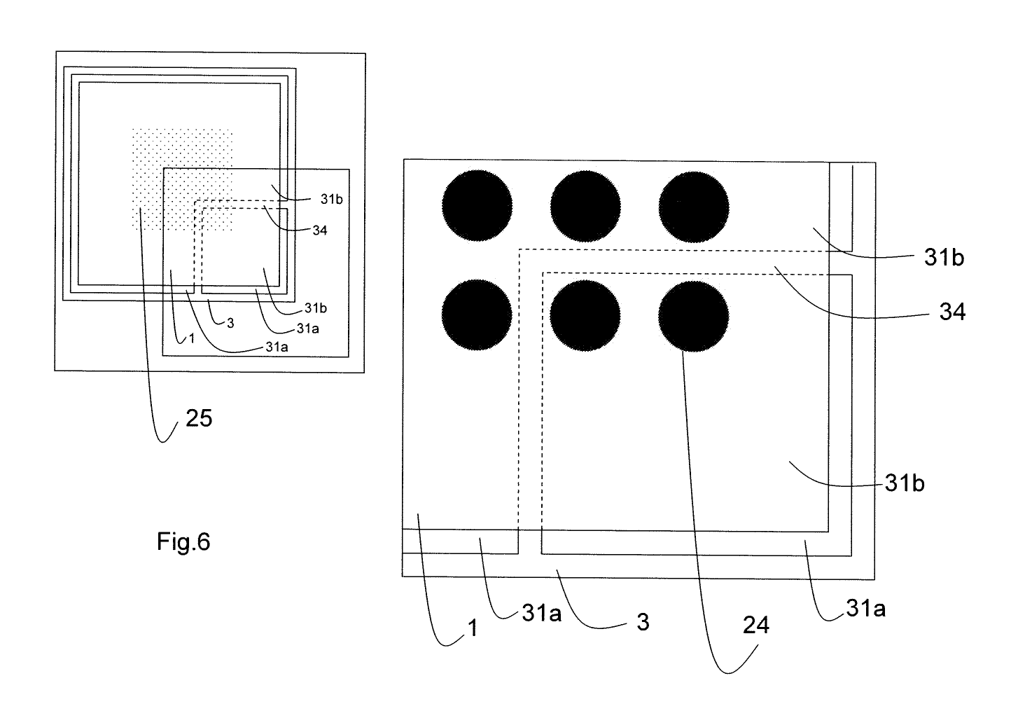

Another embodiment of the invention will be described with FIG. 6 as an example. In FIG. 6, a configuration is such that a metal layer having a potential differing from that of the other electrode is provided at one corner of the extremity of the insulating base material layer 3. This kind of metal layer is a shield layer or the like which shields an electromagnetic effect on lower layer wiring. With this configuration, a metal layer independent of the other metal layer (wiring pattern), being disposed exposed the first distance from one corner of the extremity of the solder resist 1, also has a function as one edge of a metal layer having the separation prevention effect. Also, a band shaped metal layer is formed along, and a certain distance away from, the extremity of the solder resist 1 in such a way as to be electrically isolated from the metal layer. A coated metal layer, although not shown, is formed beneath the solder resist 1.

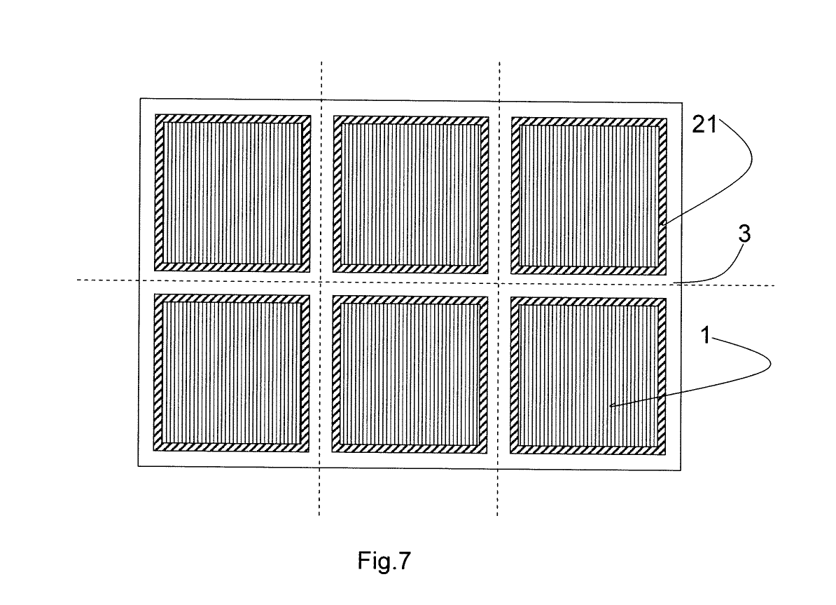

As shown in FIG. 7, a plurality of wiring patterns 21 are formed on the insulating base material layer 3, forming a multifaced wiring substrate in which the pattern of the solder resist 1 is formed for each of the metal layers of the wiring patterns 21, and it is thus possible, by carrying out a cutting along the dotted line portions, to cut the wiring substrate 100 without coming into contact with the solder resists 1 and metal layers.

In the event that there is a step of cutting the wiring substrate 100, it is possible to cause a cutting blade to last a long time by removing a metal layer such as a copper foil from the cutting portions and, by the solder resist 1 not being cut in this step, it is possible to prevent a separation from being triggered off.

It is possible to configure an electronic instrument by mounting various electronic parts on the heretofore described wiring substrate 100. As the electronic instrument, it is possible to exemplify as a notebook computer, a portable telephone, a PDA, a digital camera, a gaming machine, and the like. For example, a ball grid array substrate also being included in the electronic parts, it can be made a semiconductor package having a semiconductor element mounted in an electrode region 25 of the wiring substrate.

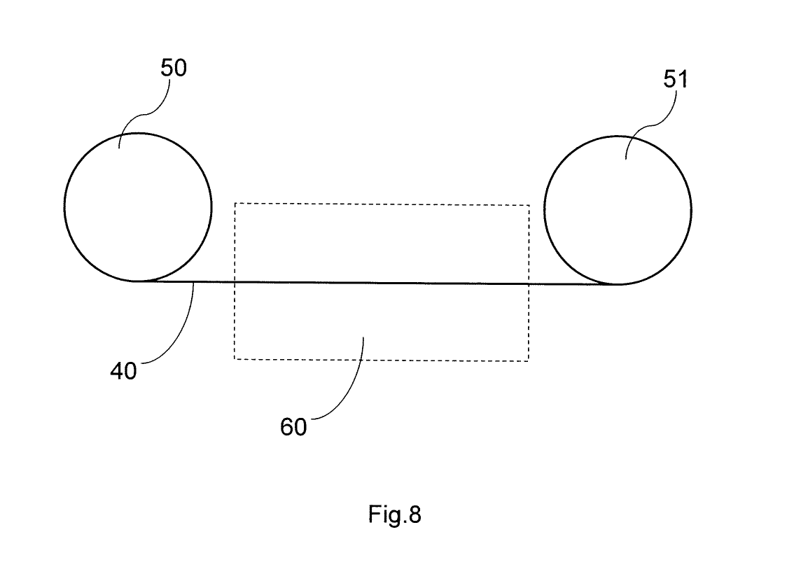

In the invention, it is possible to arrange in such a way that the solder resist 1 will not separate even in the event that the wiring substrate 100 attains a condition in which it has a total thickness of 500 μm or less, and is likely to bend. Consequently, as it is possible to arrange in such a way that the solder resist 1 will not separate even when the wiring substrate 100 is bent, it is possible to preferably apply the invention to a thin printed wiring board manufactured by a method, such as the roll-to-roll method shown in FIG. 8, which enables a lengthening process. Consequently, the wiring substrate 100 according to one embodiment of the invention, as sheets thereof, whether unifaced or multifaced, can be continuously manufactured using a roll shaped insulating substrate 3, is a wiring substrate superior in mass productivity.

A wiring substrate manufacturing method using a roll-to-roll method will be shown as an example of the wiring substrate manufacturing method according to one embodiment of the invention. As shown in FIG. 8, with the roll-to-roll method, a film base material 40 is conveyed between a wind-off section 50 and wind-up section 51 of a roll or reel, and each wiring substrate manufacturing step is processed in a processing section 60. Metal layers, in which are formed a monolayer or multilayer wiring pattern, an insulating resin layer, a via hole of the wiring pattern, which connects the individual metal layers, and the like, are formed on and in the film base material. For a lamination, it is possible to use one, or a combination, of heretofore known buildup methods such as a subtractive method and a semi-additive method.

The wiring pattern is formed, multifaced in one row or a plurality of rows, on a base material film. As the wiring pattern of the outermost layer, the edge pattern of a metal layer is formed for each block of the multifaced wiring pattern, and the solder resist is laminated and pattern-formed in such a way that the extremity thereof falls on the metal layer. As the edge pattern of the metal layer, it is possible to form the heretofore described kind of pattern of each aspect of the invention.

Lastly, by cutting a region in which no metal layer or solder resist is formed in a space between the blocks of the multifaced wiring pattern, as shown in FIG. 7, it is possible to manufacture the wiring substrate according to one embodiment of the invention at a high productivity rate. For the cutting, it is possible to use a common substrate cutting method such as a cutting using a dicing saw or a trimming die. The extremity of a solder resist positioned in the vicinity of the cutting portion is likely to be stressed but, as a metal layer is formed underneath the extremity of the solder resist, it is possible to provide a wiring substrate which has a high yield rate without causing a separation.

According to the invention, as the metal layer is formed underneath the extremity of the solder resist, it is possible to provide a wiring substrate which prevents the solder resist from separating from the wiring substrate. Furthermore, according to the invention, by disposing the metal layer in a band shape along the boundary of the solder resist, it is possible to provide a wiring substrate which efficiently prevents a separation using a small amount of region. Furthermore, according to the invention, as it is possible to cope with a positional error in a lamination step by a region in which a metal layer is exposed from the solder resist, and a region in which a metal layer overlaps the solder resist, forming a certain width, it is possible to provide a wiring substrate which stably maintains the quality.

### Example 1

Steps of a degreasing, a pickling, a washing, and a drying are carried out using a copper clad laminate, to either surface of which a copper foil is laminated, as the insulating base material layer 3 using a polyimide resin. Next, the substrate is coated, in a dark room, with a photosensitive solder resist 1 indicated by the trade name “PSR-4000 AUS308”, manufactured by Taiyo Ink Mfg. Co., Ltd., in such a way as to have a thickness of 20 μm on one surface of the insulating base material 3, and the solder resist 1 is dried at 90° C. Subsequently, the solder resist 1 is heated at 150° C. for 30 minutes, and completely cured.

Next, the wiring substrate 100 to which this solder resist 1 is laminated is left for 168 hours in an environment of a temperature of 125° C. and a humidity of 100%, and an acceleration test is implemented thereon.

### Comparison Example 1

The wiring substrate 100 is formed, and the acceleration test is carried out, using the same step as that of Example 1, except that no copper foil is laminated onto the insulating base material layer 3 using a polyimide resin, and no metal layer is formed beneath the solder resist 1.

When confirming the adhesion between the solder resist 1 and the insulating base material layer 3, using a grid tape method, after the acceleration test finishes, all of 100 solder resists 1 on the metal layer 2 using a copper foil adhere to the insulating base material layer 3. On the other hand, six of 100 solder resists 1 on the insulating base material layer 3 adhere to the insulating base material layer 3, while the remaining 94 are separated.

As a result of this, it is confirmed that the solder resist 1 is less likely to separate from the metal layer 2 using a copper foil than from the insulating base material layer 3, and that the invention is effective.

The heretofore described grid tape method is one carried out by a method provided in the Japanese Industrial Standards JIS K5400.8.5.2. The solder resist 1 on the metal layer 2 is cut into 100 1 mm by 1 mm squares, and a tape is attached and peeled, thus checking the solder resist 1 for a separation of each square.

### Example 2

A copper clad laminate, to either surface of which a copper foil is laminated with a polyimide resin as the insulating base material layer 3, is used to form the pattern of the solder resist 1 on the copper foil and, by carrying out an etching and a resist removal, a metal layer having a potential differing from that of the other electrode, a metal layer other than a ground layer, and a band shaped dummy wiring pattern such as surrounds the metal layers, are formed at a corner of the wiring substrate 100. The dummy wiring pattern, being spaced a distance of 50 μm away from the ground layer, is arranged in such a way that the line width thereof is 100 μm.

Next, the metal layers are coated, in a dark room, with the trade name “PSR-4000 AUS308” manufactured by Taiyo Ink Mfg. Co., Ltd. as the solder resist 1, in such a way as to have a thickness of 20 μm so that one portion of the ground layer and dummy wiring pattern is exposed, and the solder resist 1 is dried at 90° C. Subsequently, the solder resist 1 is heated at 150° C. for 30 minutes, and completely cured, manufacturing the wiring substrate 100 according to one embodiment of the invention.

### Comparison Example 2

The wiring substrate 100 is formed using the same metal layer wiring pattern and the same step, except that no dummy wiring pattern is formed.

An adhesive tape provided in the Japanese Industrial Standards JIS Z1522 is attached to each wiring substrate 100 in such a way as to cover the solder resist 1 and metal layers and, without being cut, is separated from one of the edges including the ground layer. With regard to test conditions other than this, the test is carried out under the same conditions as those of Example 1.

With the wiring substrate 100 of Example 2, no separated portion exists for all of ten samples while, with the wiring substrate 100 of Comparison Example 2, in nine of ten samples, a separation occurs in one or a plurality of corner portions of the solder resist 1.

### Example 3

A wiring substrate is manufactured by the roll-to-roll method shown in FIG. 8. By using a copper clad polyimide film, on either surface of which is formed a copper foil, as a film base material, single-sided copper clad polyimide films are sequentially laminated to either surface of the polyimide film, forming a six-layer wiring substrate. The total thickness of the substrate at this time is 250 μm. A wiring pattern formed of a copper foil is formed in a metal layer by a subtractive method, and a polyimide film which forms an upper layer is laminated thereto by a lamination, using an adhesive layer.

The wiring pattern is multifaced, as shown in FIG. 7, and a loop shaped dummy wiring pattern having a width of 100 μm is formed on the periphery of each wiring pattern block of the outermost layer. Each multifaced wiring pattern is coated with the solder resist 1 in such a way that the solder resist has a thickness of 20 μm, the solder resist 1 is dried, and pattern-formed in such a way that an electrode portion, and one portion of the dummy wiring pattern, are exposed.

After the above steps are processed by the roll-to-roll method, the wiring substrate is cut in a region in which no metal layer exists between the solder resists, with a cutter, for each block of the wiring pattern. When checking the condition of the solder resist for the cut samples of the wiring substrate 100 according to one embodiment of the invention, no sample exists in which a separation occurs.

What is claimed is:

1. A wiring substrate comprising: an insulating base material layer; a metal layer on the insulating base material layer; and a solder resist laminated to the most superficial surface of the wiring substrate above the insulating base material layer, wherein
the metal layer has a loop shaped pattern formed along the edge of the insulating base material layer, and
the solder resist is formed in such a way that one portion of the pattern is exposed from, and one portion covered with, an extremity of the solder resist on the edge side, along the pattern.

2. A wiring substrate comprising: an insulating base material layer, a metal layer on the insulating base material layer, and a solder resist laminated to the most superficial surface of the wiring substrate above the insulating base material layer, wherein
the metal layer has a discontinuous edge pattern formed along the edge of the insulating base material layer,
the solder resist is formed in such a way that one portion of the pattern is exposed from, and one portion covered with, an extremity of the solder resist on the edge side, along the pattern, and
a space between discontinuous portions of the pattern in which are formed the extremities of the solder resist is 1 mm or less.

3. The wiring substrate according to claim 2, wherein
ground wiring is included in the pattern.

4. The wiring substrate according to claim 1, wherein
the line width of the pattern is 20 μm or more.

5. The wiring substrate according to claim 1, wherein
the width of a portion in which the pattern and the solder resist overlap each other is at least 10 μm.

6. The wiring substrate according to claim 1, wherein
the metal layer is either a layer formed of a copper foil or a layer formed of a copper plating layer and a metal paste.

7. The wiring substrate according to claim 1, wherein
the total thickness of the wiring substrate is 500 μm or less.

8. A semiconductor package, wherein a semiconductor element is mounted on the wiring substrate according to claim 1.

9. A semiconductor package, wherein a semiconductor element is mounted on the wiring substrate according to claim 2.

10. An electronic instrument comprising the wiring substrate according to claim 1.

11. An electronic instrument comprising the wiring substrate according to claim 2.

12. A method of manufacturing the wiring substrate according to claim 1, wherein
the substrate multifaced with a plurality of the patterns is cut in a region in which the metal layer and the solder resist do not exist between the patterns.

13. A method of manufacturing the wiring substrate according to claim 2, wherein
the substrate multifaced with a plurality of the patterns is cut in a region in which the metal layer and the solder resist do not exist between the patterns.

14. The method of manufacturing the wiring substrate according to claim 12, wherein
the substrate is processed by a roll-to-roll method using a roll shaped insulating base material layer.
